(19) United States
(12) Patent Application Publication
(10) Pub. No.: US 2004/0178175 A1
(43) Pub. Date: Sep. 16, 2004

(54) Atomic layer deposition for high temperature superconductor material synthesis

(76) Inventors: Michael J. Pellin, Naperville, IL (US); John N. Hryn, Naperville, IL (US); Jeffrey W. Elam, Downers Grove, IL (US)

Correspondence Address: CHERSKOV & FLAYNIK, THE CIVIC OPERA BUILDING, 20 NORTH WACKER DRIVE, SUITE 1447, CHICAGO, IL, 60606, US

(21) Appl. No.: 10/799,181

(22) Filed: Mar. 12, 2004

Related U.S. Application Data
(60) Provisional application No. 60/454,160, filed on Mar. 12, 2003.

(51) Int. Cl. C23C 16/00; C23F 1/00

(52) U.S. Cl. 216/58; 427/248.1

(57) ABSTRACT

An improved device and process for atomic layer deposition (ALD) is provided. A more rapid deposition of layers is accomplished by a continuous flow of reactant moieties. The first moiety, carried by an inert carrier gas, is deposited as a monolayer. The flow is then switched to the second moiety, also carried by an inert gas, which is deposited as a monolayer and which reacts with the first moiety thereby forming a product moiety monolayer. The process is repeated with continual switching of flow between the two different reactant moieties. This allows for the deposition of many layers of the product moiety Any unreacted moiety molecules and unadsorbed product moiety molecules are swept out by the carrier gas. The capability exists to use more than three reactant moieties and thus form complex materials.

This patent application claims the benefit of U.S. Provisional Patent Application No. 60/454,160, filed Mar. 12, 2003.

### CONTRACTUAL ORIGIN OF THE INVENTION

The United States Government has rights in this invention pursuant to contract number W-31-109-ENG-38 between the U.S. Department of Energy and the University of Chicago representing Argonne National Laboratory.

### BACKGROUND OF THE INVENTION

1. Field of the Invention

This invention relates to an improved method and reactor for preparing high temperature superconducting conductors, and more particularly, this invention relates to an improved method and apparatus for preparing high temperature superconducting conductors using atomic layer deposition (ALD).

2. Background of the Invention

Since the discovery of high temperature superconductivity (HTS), a great deal of effort has been devoted to the development of HTS materials for electrical power usage. A primary motivation for these efforts derives in part from the fact that ˜10% of the energy currently transmitted over copper cables is lost to resistive heating. Consequently, the potential savings resulting from the switch to HTS cables for power transmission could be enormous. Further, many devices in the power industry (transformers, storage devices, etc.) would show major efficiency improvements with the use of high critical current, J_{c}, wires.

The commercial use of high temperature superconducting (HTS) materials such as YBa₂Cu₃O_{7-δ} (YBCO) has been limited by the difficulty of synthesizing these complex multi component oxides. Conventional coated conductor fabrication processes have only achieved YBCO HTS tape lengths of several meters. The greatest barriers to commercializing HTS wires are relatively slow growth rates of current physical vapor deposition techniques relying on “line-of-sight” and the difficulty in aligning the individual YBCO crystals leading to high resistance “weak links”.

Through the use of atomic layer deposition (ALD) techniques, it is possible to deposit HTS materials on high aspect ratio substrates, such as thin tubes, coiled HTS coated conductor substrates, nano-porous anodic alumina structures, and microelectromechanical systems (MEMS) devices. ALD is a chemical vapor deposition (CVD) related chemical thin film deposition method that relies on sequential surface reactions. ALD utilizes a pair of self-limiting chemical reactions between gaseous precursor moiety molecules and the surface of a solid substrate. The gaseous precursor moieties are alternately introduced onto the substrate. Between the introduction of each precursor, the reactor is either purged with an inert carrier gas or evacuated. The requirement that the reactor be purged or evacuated does, however, slow the deposition process, especially if multi layers of the product film moiety are desired.

Under properly adjusted conditions of deposition temperature, reactant moiety dose, and length of precursor and purge pulses, a monolayer of each reactant moiety is left on the surface after the purge sequence. FIG. 1 depicts this scenario. Moiety A is deposited onto the surface with the subsequent deposition of moiety B. Exposing the surface to reactant moiety A results in the self-limiting adsorption of a monolayer of the A specie. The resulting surface becomes the starting substrate for reaction with reactant moiety B. Subsequent exposure to moiety B covers the surface with a monolayer of B specie. A reaction then takes place between the two species to form a monolayer of desired product. Any byproducts of the surface reaction are swept away by the inert carrier gas. This kind of ALD system has been reported by the inventors. J. W. Elam, M. D. Groner, and S. M. George, “Viscous Flow Reactor with Quartz Crystal Microbalance for Thin Film Growth by Atomic Layer Deposition,” Reviews of Scientific Instruments, 73(8), 2981-2987 (August 2002), and incorporated herein by reference.

For HTS superconductor materials, three deposited layers are required on a substrate: 1) a buffer layer such as yttria-stabilized zirconia (YSZ), an HTS layer (YBCO), and a capping layer such as copper (Cu), tungsten (W), or zinc oxide (ZnO) are required. FIG. 2 depicts the architecture of such a structure.

The controlled deposition of alternating atomic layers of different materials afforded by ALD can facilitate the growth of multilayer YBCO/Ca-doped YBCO films, thus permitting the selective doping of the YBCO grain boundaries to overcome the “weak-link” problem. FIG. 3 depicts the architecture of this structure. Alternating layers of YBa₂Cu₃O _{7-δ} and Y₁₋ₓCaₓBa₂Cu₃O_{7-δ} are deposited. Subsequent annealing of the structure can cause Ca ion migration to the grain boundary. G. Hammerl, et al., “Enhanced Supercurrent Density in Polycrystalline YBa₂Cu₃O₇-δ at 77K from Calcium Doping of Grain Boundaries,” Nature (London), 407, 162-164 (2000). Thus, ALD relaxes the stringent requirements on the currently used bi-axially textured substrates, and provides a faster and more economical route to the fabrication of long-length superconducting tapes.

ALD relies on the gaseous diffusion of precursor moiety molecules to reach all regions of the substrate. This quality, combined with the self-limiting surface chemistry that terminates after the completion of the deposition of each monolayer, allows substrates with extremely high aspect ratios, such as cylindrical objects, to be coated thoroughly and uniformly. This feature has been put to great advantage. N. D. Hoivik, et al., “Atomic Layer Deposition of Conformal Dielectric and Protective Coatings for Released Microelectromechanical Devices,” Sensors and Actuators A 103, 100-108 (February 2003); and J. W. Elam, et al., “Conformal Coating of Ultrahigh Aspect Ratio Anodic Alumina Membranes by Atomic Layer Deposition,” Chemistry of Materials (Sep. 9, 2003); 15(18) 3507-3517. These lafter two articles are incorporated herein by reference.

U.S. Pat. No. 6,673,701 awarded to Marsh, et al. on Jan. 6, 2004 discloses a method to deposit as many as three precursor and product moieties via gas pulses onto substrate surfaces via ALD.

U.S. Pat. No. 6,503,330 awarded to Sneh, et al. on Jan. 7, 2003 discloses a method and apparatus for an ALD system to deposit precursor and product moieties on substrate surfaces.

U.S. Pat. No. 6,468,924 awarded to Lee, et al. on Oct. 22, 2002 discloses a method and apparatus for an ALD system to deposit precursor and product moieties on substrate surfaces.

U.S. Pat. Nos. 6,428,859 and 6,416,822 awarded to Chiang, et al. on Aug. 6, 2002 and Jul. 9, 2002, respectively, disclose a method and apparatus for modulated ion-induced atomic layer deposition (MII-ALD). A continuous deposition method is provided, but requires evacuation of the reaction zone after the deposition of each precursor moiety.

U.S. Pat. No. 6,270,572 awarded to Kim, et al. on Aug. 7, 2001 discloses a method and apparatus for an ALD system to deposit precursor and product moieties on substrate surfaces.

U.S. Pat. No. 6,174,809 awarded to Kang, et al. on Jan. 16, 2001 discloses a method and apparatus for an ALD system to deposit precursor moieties on substrate surfaces and carry out reactions to deposit metals.

U.S. Pat. No. 6,143,659 awarded to Leem on Nov. 7, 2000 discloses a method and apparatus for an ALD system to deposit precursor moieties on substrate surfaces and carry out reactions to deposit aluminum metal.

U.S. Pat. No. 6,042,652 awarded to Hyun, et al. on Mar. 28, 2000 discloses a method and apparatus for an ALD system to deposit precursor and product moieties on multiple substrate surfaces.

U.S. Pat. No. 5,879,459 awarded to Gadgil, et al. on Mar. 9, 1999 discloses a method and apparatus for an ALD system using a vertically-stacked process reactor and cluster tool system to deposit precursor and product moieties on substrate surfaces. A method is provided to deposit upon either single or multiple substrates.

Several of the aforementioned patents teach an ALD apparatus and process whereby a precursor moiety gas is allowed to chemisorb or physisorb onto a substrate's surface followed by evacuation of the substrate's area with a mechanical vacuum pump, after which the diftsion/adsorption step is repeated with another precursor gaseous moiety. None of the aforementioned patents provide for continuous, uninterrupted, multilayer ALD or for the deposition and reaction of more than three precursor moieties. State of the art ALD techniques for multi-layer deposition requires using different methods and several instruments.

A need exists in the art for a method and device by which multilayer atomic deposition and synthesis can be continuously carried out without interruption. The method and device should also allow for continuous deposition and reaction between a plurality of reactant moieties to form complex materials on substrates' surfaces.

### SUMMARY OF THE INVENTION

It is an object of the present invention to provide a method and device for atomic layer deposition that overcomes many of the disadvantages of the prior art.

Another object of the present invention is to provide an improved method for formation of multi layers of a coating material on a substrate using ALD. A feature of the invention is that a computerized gas pulse switching method is used to introduce the precursor reactant moieties. An advantage of the invention is that layers are deposited more rapidly, and without stopping the process to change the reaction chamber's atmosphere.

Still another object of the present invention is to provide a basic ALD method for continuous deposition of layers on a substrate. A feature of the invention is that the method uses an inert carrier gas to transport precursor reactant moieties to the reaction zone. Another feature is that the carrier gas doubles as a sweep gas to remove unreacted reactant moieties and unadsorbed product moieties from the reaction zone, such that evacuation using a pump is not required. This feature provides an uninterrupted fluid stream containing a succession of reaction moieties separated by inert moieties. An advantage of the invention is that the method has a greater rate of productivity, and thus is less expensive.

Yet another object of the present invention is to provide a method that allows for the deposition of complex moieties such as complex oxides on the substrate surface. A feature of the invention is that multiple ports for precursor moiety ingress can be provided. An advantage of this is that the method can provide a greater array of substrate coatings to suit different needs.

Still another object of the present invention is to provide an apparatus that can deposit the three layers typically required for HTS superconductor materials. A feature of the invention is that all three layers can be deposited with the same apparatus without moving, removing, or otherwise repositioning the substrate. An advantage of this feature is that it provides for a more rapid and efficient HTS formation process, and thus considerable time and cost savings.

It is yet another object of the present invention to provide an ALD method to deposit YBCO films on conformationally complex substrates to form HTS superconductors. An feature of the invention is that deposition of films can be made on Ushadowed” surfaces of the substrate, surfaces that can not be seen or easily reached. An advantage of this feature is that long HTS wires can be produced at orders of magnitude higher rates. Aspect ratios as high as approximately 5000 Ud (Length/diameter) are accommodated.

Yet another object of the invention is to provide an ALD method that can more definitively resolve the “weak-link” problem. A feature of the invention is that a YBCO/Ca-doped YBCO heterostructure can be deposited on a substrate with subsequent annealing of the superstructure. An advantage of this feature is that Ca ions diffuse into and along the grain boundaries of the structure allowing for high critical current, J_{c}. Yet another advantage is that this manner of resolution of the “weak-link” problem is faster, and thus more economical.

Another object of the present invention is to provide a more automated ALD method. A feature of the invention is that molecular precursor moieties are used as opposed to elemental precursors. An advantage of the invention is that the ALD can be carried out at significantly lower temperatures so that heat-sensitive electronic devices can be used within the ALD apparatus. The process enables the production of homogeneous, conformal films.

Briefly the invention provides a process for using a reaction sequence to deposit layers on a substrate, the process comprising placing the substrate in a chamber; heating the chamber; transporting gaseous precursor molecules of a first moiety via an inert carrier gas; exposing the substrate to gaseous precursor molecules of the first moiety, whereupon a first monolayer of the first gaseous precursor moiety molecules is formed upon the substrate by being adsorbed by the substrate; sweeping out the unadsorbed molecules of the first moiety via the inert carrier gas; transporting gaseous molecules of a second moiety via an inert carrier gas; exposing the substrate and monolayer to gaseous molecules of a second moiety at a concentration and for a time sufficient for the molecules of the second moiety to be absorbed to the first monolayer; reacting the first moiety of the monolayer with the second moiety so as to form a new monolayer of product moiety molecules; and removing the unreacted molecules of the second moiety and the unadsorbed molecules of the product moiety.

The invention also provides a device to continuously deposit atomic layers on substrates, the device comprising valves to release gases; a computerized switch that controls the valves and gas release; mechanical vacuum pumps that cause gas flow; heaters that heat substrates upon which deposition and reaction is carried out.

### BRIEF DESCRIPTION OF THE DRAWINGS

The invention together with the above and other objects and advantages will be best understood from the following detailed description of the preferred embodiment of the invention shown in the accompanying drawing, wherein:

FIG. 1 is a schematic diagram of a binary reaction sequence;

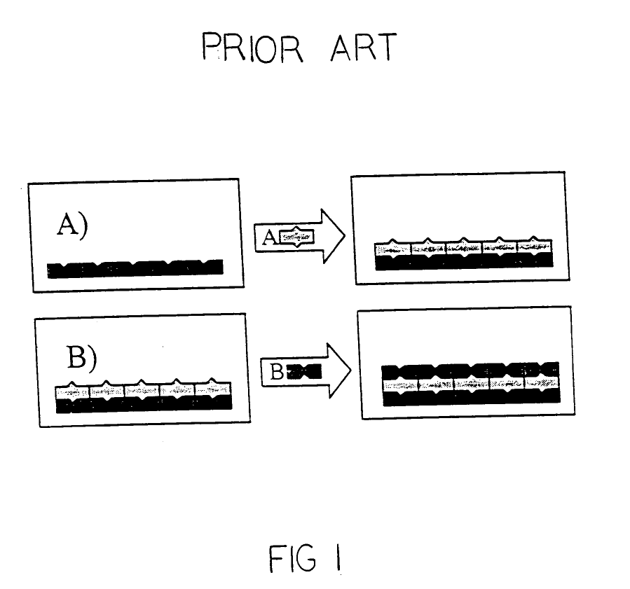

FIG. 2 is a schematic diagram of a coated conductor fabrication sequence;

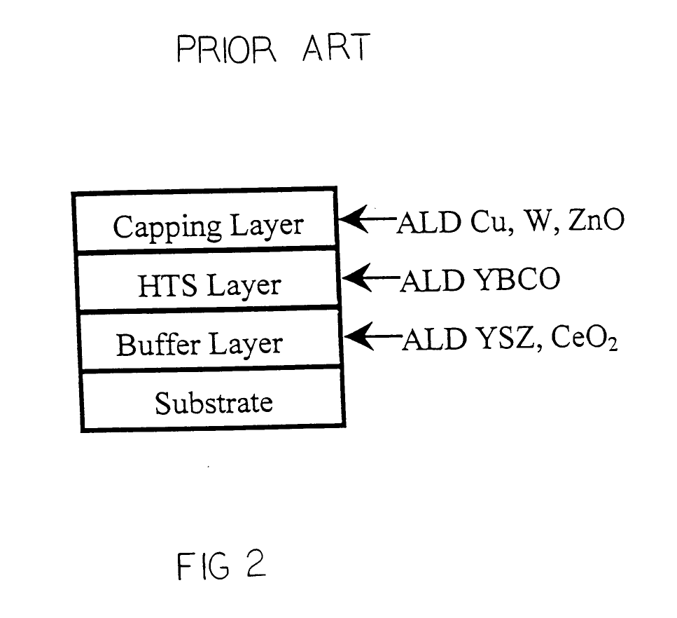

FIG. 3 is a schematic diagram of multilayer YBCO/Ca-doped YBCO films on a substrate, in accordance with features of the present invention;

FIG. 4 is a schematic diagram of salient features of a viscous flow ALR reactor, in accordance with features of the present invention;

FIG. 5 is a plot of the thickness of zinc oxide (ZnO) and alumina (Al₂O₃) monolayers onto a target substrate as a function of number of deposition cycles, in accordance with features of the present invention;

FIG. 6 is a plot of the mass of a mixed zinc and aluminum oxide deposited on a substrate as a function of the number of deposition cycles, in accordance with features of the present invention; and

FIGS. 7A-C is a schematic diagram of a coiled metal tape and subsequently coated via ALD, in accordance with features of the present invention.

### DETAILED DESCRIPTION OF THE INVENTION

The inventors have found that improved atomic layer deposition can be achieved by utilizing a reactor that provides a continuous and viscous flow of inert carrier gas to transport precursor reactant moieties to sample substrates, and to purge or sweep the unused precursor reactant moieties out of the reaction zone. More specifically, the inventors have found that using a computerized gas pulse switching method for introducing precursor reactant moieties provides for the rapid and uninterrupted deposition of multi layers of high-purity product moiety film on a plurality of substrates. The invented process allows for a layer-by-layer deposition (also called conformal deposition) of film on whatever surface of the substrate is exposed to the gaseous atmosphere. Generally, all surfaces of the substrate are coated so as to enhance the superconductivity characteristics thereof.

Film deposition on substrates is also feasible using short-duration pulses of pure precursor moiety gases without any inert carrier gas.

The amount of precursor moiety gas required is empirically determined to saturate the active sites on the substrate's surface. The saturation aids to insure dense, smooth, pinhole-free films which are defect-free and continuous. Preferably, substantially all of the active sites are saturated with the precursor moiety. (However, there may be some instances where the atmosphere of the reaction zone is intentionally starved of a certain precursor moiety so that not all active sites are occupied by that precursor moiety.)

The deposition is rapid and self-limiting. Once a monolayer of one moiety is formed, additional exposure to that same moiety results in no substantial additional deposition. Only exposure to a second moiety which is reactive towards the first moiety deposited on the substrate surface results in the deposition of any additional surface activity. In this instance, whereby ample amounts of the first moiety are fed to the reaction zone, the second moiety is deposited upon the first layer, and not directly to the substrate.

In addition, the inventors have found that using molecular precursor moieties allows for the use of reaction zone temperatures from 200 to 400C.° lower than used for elemental precursor moieties. As such, typical reaction zone temperatures do not exceed 400° C. in the invented device and process. This approach aids in the use of electronic devices such as quartz crystal microbalances within the apparatus, and even within the reaction zone, a flow tube. The flow tube can be used, if needed, at temperatures as high as 1000° C.

Tables 1 through 4 list possible precursors for the ALD of HTS superconductors.

TABLE 1
Yttrium (Y) Precursor Moieties and Deposited Films.

| Precursor | Film |
|---|---|
| Y(thd)₃ | YBCO or Y₂O₅ |
| Y(thd)₃.4-tertbutyl-pyridine-N-oxide | YBCO |
| Y(methylcyclopentadiene)₃ | YBCO |
| Y(hfac)₃.H₂O | |
| Y(thd)₃ triglyme | |
| Y(butylcyclopentadiene)₃ | |

TABLE 2
Barium Precursor Moieties and Deposited Films

| Precursor | Film |
|---|---|
| Ba(methylcyclopentadienyl)₂.(THF) | BaTiO₃ |
| Ba(thd)₂ | YBCO |
| Ba(thd)₂.NR₃ | BaO |
| Ba(hfac)₂.tetraglyme | YBCO |
| Ba(tdf)₂.tetraglyme | YBCO |
| Ba(fod)₂ | YBCO |
| Ba(thd)₂.(tetraethylenepentamine)₂ | YBCO |
| Ba(thd)₂.tetraglyme | |
| Ba(thd)₂.triglyme | |
| Ba(hfac)₂ | |
| Ba(n-propyltetramethylcyclopentadienyl)₂ | |

TABLE 3
Copper Precursor Moieties and Deposited Films

| Precursor | Film |
|---|---|
| Cu(hfac)₂ | Cu |
| Cu(thd)₂ | YBCO or CuS |
| Cu(acac)₂ | YBCO |
| Cu(fod)₂ | YBCO |

TABLE 4
Calcium Precursor Moieties and Deposited Films

| Precursor | Film |
|---|---|
| Ca(thd)₂ | CaO |
| Ca(thd)₂.tetraethylenepentamine | CaS |
| Ca(fod)₂ | CaS |

Notes for tables 1-4.
thd = 2,2,6,6-tetramethyl-3,5-heptanedioneate;
acac = 2,4-pentadione;
hfac = 1,1,1,5,5-hexafluoro-2,4-pentanedioneate;
fod = 6,6,7,7,8,8,8-heptafluor-2,2,-dimethyl-3,5-octanedioneate;
tdf = 1,3-perfluoropropyl-1,3-propanedionate.

A number of possible oxidizing moieties can allow the ALD of YBCO and Ca-doped YBCO films. The oxidizing moieties include, but are not limited to, oxygen (O₂ ozone (O₃), water, nitrous oxide (N₂O), and hydrogen peroxide (H₂O₂). Plasmas formed from these oxidizing moieties can also be used for ALD. Annealing in oxygen is sometimes used to obtain the optimal oxygen content in the YBCO films to give the films the best superconducting properties. The annealing procedures can be performed in the instant invention following deposition of the YBCO film.

The inert carrier gas is selected from the group consisting of nitrogen (N₂), argon (Ar), and helium (He). However, for the formation of nitrides as a product film moiety on substrate surfaces, preferably, nitrogen should not be used as a carrier gas inasmuch as the nitrogen would become part of the reaction.

Product deposition film moieties are oxides selected from the group that includes, but is not limited to, yttrium oxide (Y₂O₃), barium oxide (BaO), cupric oxide (CuO), zinc oxide, (ZnO), alumina (Al₂O₃), and mixed yttrium (Y)-barium (Ba)-calcium (Ca) oxides.

Substrates must be chemically reactive.

A salient feature of the instant invention is that a computerized precursor moiety gas pulse switching system allows for rapid deposition of monolayers. The computerized system comprises a computer, with the appropriate programming, that drives a pneumatic valve which is the actual gas pulse switch.

Device Detail

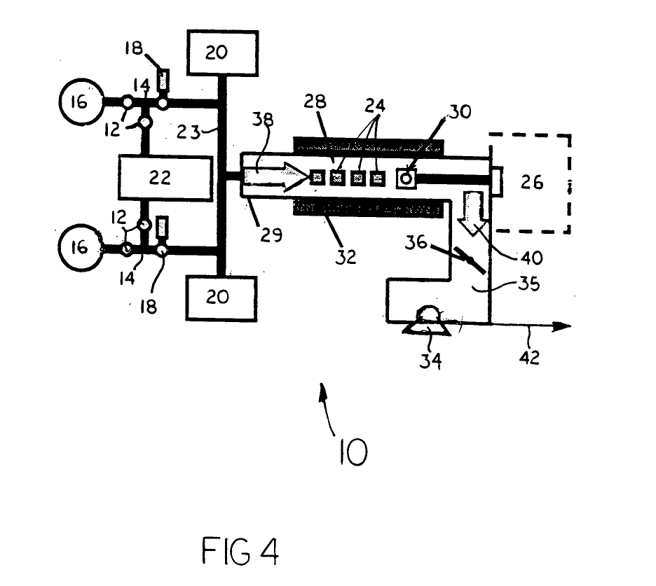

A schematic diagram of the viscous flow reactor device and process is depicted in FIG. 4 as numeral 10. The reactor 10 incorporates pneumatic valves 12 that serve as the points of ingress 14 for precursor reactant moieties 16 into the system. Needle valves 18 regulate the mixture of the precursor moieties with inert carrier gas 20. Prior to the admission of any gases into the system, a mechanical vacuum pump 22 evacuates the points of ingress 14.

A salient component of the reactor 10 is a reaction zone 28 defined by an enclosure 29. The enclosure 29 is positioned intermediate the gas supplies 16, 20 and a means 34 for evacuating gas from the enclosure 29. Generally, the enclosure 29 serves to control the reaction atmosphere and therefor prevent uncontrolled fluid communication with the environment.

Sample substrates 24 are loaded through a sample loading area 26 into a reaction zone 28. A quartz crystal microbalance (QCM) 30 rests within the reaction zone 28. To facilitate reaction, the reaction zone 28 containing the substrate 24 and the microbalance 30 should be in thermal communication with heating elements such as heaters 32.

After the substrate is placed in the reaction zone 28, the reaction zone 28 is evacuated by the gas evacuation means 34, in this instance a mechanical vacuum pump. Fluid communication between the pump 34 and the reaction zone 28 is facilitated via a conduit 35 and regulated by a throttle valve 36 which is positioned along the conduit and intermediate the zone 28 and the pump. The flow of gases is from the high pressure (i.e. upstream) side 38 of the flow tube to the low pressure (i.e., downstream) side 40 with no back flow permitted. Unused gas egress is facilitated by negative pressure from a second mechanical vacuum pump 34.

Matters of control of all pulses, both of reactants, and of inert gases for applications of precursor moieties and purges of unused reactant and unadsorbed product moieties are disclosed in detail in the J. W. Elam et al. Reviews article incorporated by reference supra.

The instant invention deposits films that are dense, smooth, and pinhole free. Further, by adding additional reactant channels to the viscous flow reactor, complex oxide materials can be deposited by alternating between the ALD of the components.

The additional channels and gas pulse switching capability allows for control of the film composition at the atomic level by adjusting the relative amounts of the different components incorporated into the ALD film.

Protocol

The process commences with the loading of precursor moieties into their respective containers. The precursor moieties, often solids at room temperature, are then heated to vaporization, usually less than 200° C. A target substrate(s) is loaded into the reaction chamber 28 through the sample loading area. The entire system is then evacuated by the mechanical vacuum pumps which are left running through the entire process.

An inert gas such as nitrogen, helium or argon is allowed to flow through the system, with the system remaining at a pressure of ˜1 Torr for the duration of the complete deposition. Once a substrate(s) is loaded into the flow tube, and the system evacuated, a continuous gas flow is established. The substrate is subsequently heated to a preselected temperature. Reaction zone temperatures range typically from about 200° C. to 400° C.

Once the preselected temperature has been attained, the first gaseous precursor moiety is allowed to enter, as a pulse of pure gas, or with an inert gas such as nitrogen acting as a carrier, into the reaction zone 28. Pressure and pulse values will vary, depending on the precursors utilized and the ultimate topographical configuration desired. In one empirically derived set of parameters, total gas pressure is typically ˜1 Torr. Preferably, the gas flow rate ranges from about 5 to 20 liters per hour and the precursor gas pulse duration ranges from of about one one-tenth (0.1) of a second to 10 seconds (sec). A pulse of the first precursor moiety can be followed immediately by a pulse of the next precursor moiety either from the same fluid stream or from different ingress portals. Each pulse is self-purging. In the event of pulses of pure gaseous precursor moieties, a purge pulse of inert carrier gas intervenes between pulses of pure precursor moieties.

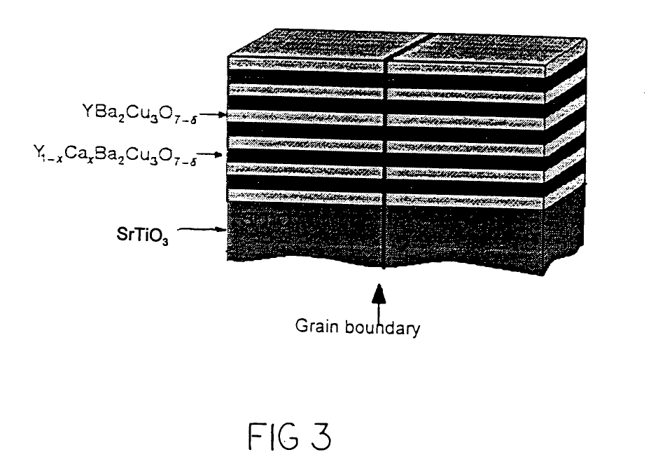

The inert carrier gas flow transports the precursor moieties to the reaction zone and sweeps the unused reactants and unadsorbed reaction products out of the reaction zone. Since the mechanical vacuum pumps are continually running, the chemical moieties go through the pumps which vent into a “buming box” (not shown in FIG. 3), in which the materials are destroyed, and the “box” then vents into the atmosphere.

In addition to heating the precursor moieties, the valves 12, 18, and conduits 23, 35, also can be heated by resistive coil heaters, heated air, or some other thermal conduction means.

The time lapse between pulses can be of any duration, but the emphasis of the instant invention is upon rapid deposition of films.

The thickness of a typical deposited monolayer is from about 0.2 angstrom (Å) [2 nanometers (nm)] to 5 Å (5 nm). Specific thicknesses of layers are dependent, however, upon the nature of the deposited substance.

The film growth rate is up to about one micron (μ) per hour.

The quartz crystal microbalance (QCM) allows for ALD film thickness measurements in situ.

The following example is only to illustrate how a reaction can be carried out between two precursors to leave a monolayer of product on a substrate, e. g., one method of depositing a monolayer of alumina, Al₂O₃, on a substrate. Thus, the example serves to illuminate, on a molecular level, the general process of ALD with the instant invention.

### EXAMPLE

Consider the following binary A-B reaction cycle, illustrated by Equations 1 and 2, for the ALD of alumina, Al₂O₃ via the reaction of trimethyl aluminum (TMA) with hydroxyl (OH).

Reaction |—Al—Al—OH*+Al(CH₃)₃→|—Al—O—Al(CH₃)₂*+CH₄ Equation 1

Reaction B |—Al—O—Al(CH₃)₂*+2H₂O→|—Al—O—Al—OH*+2CH₄ Equation 2

In Equations 1 and 2, the asterisks designate moieties adsorbed to the substrate surface, the “|—” indicates the substrate surface, and the equations have been simplified to show only one surface active site. The actual scheme involves several active sites at once. In Equation 1, the substrate surface is initially covered with hydroxyl (OH) moieties formed by exposure of the Alumina substrate's surface to water. The hydroxyl moieties react with TMA to deposit a monolayer of aluminum atoms that are terminated by methyl (CH₃) species, and releasing methane (CH₄) as a reaction byproduct. This methane can be shunted to a reclamation system to protect the system. TMA is not reactive to the methyl termini protruding from the now covered surface. Thus, due to the methyl termini, additional exposure of this surface to TMA gives no additional growth on the surface beyond the one monolayer already present on the surface.

In Equation 2, subsequent exposure of this new monolayer surface to water displaces the two methyl moieties, and leaves hydroxy in their place. The hydroxy reacts with a pulse of fresh TMA and creates another monolayer of Al—O ionic bonds. Methane is once again released as a byproduct. The net effect of one AB cycle is to deposit one monolayer of alumina on the substrate surface. Multiple cycles produce multiple layers.

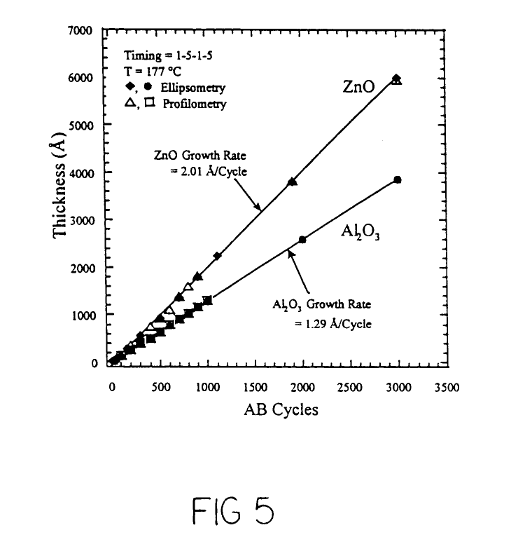

FIG. 5 displays the results of ellipsometry and profilometry thickness measurements for zinc oxide (ZnO) and alumina ALD films. These films were prepared in the viscous flow ALD reactor using alternating exposures of the substrate (e.g., a silicon semiconductor wafer) to diethyl zinc (DEZ) and water leading to the deposition of zinc oxide films. This deposition is followed by exposure of the now covered substrate to TMA and water in the production and deposition of alumina films onto the substrate.

The zinc oxide and alumina show very linear growth rates even after 3000 AB-type cycles as described supra. This number of cycles, three thousand, is sufficient to produce high temperature superconductors (HTS) with coatings of thicknesses of about 1 micrometers (μm). Generally, the invented process can facilitate the formation of coating thicknesses of up to approximately 10 microns.

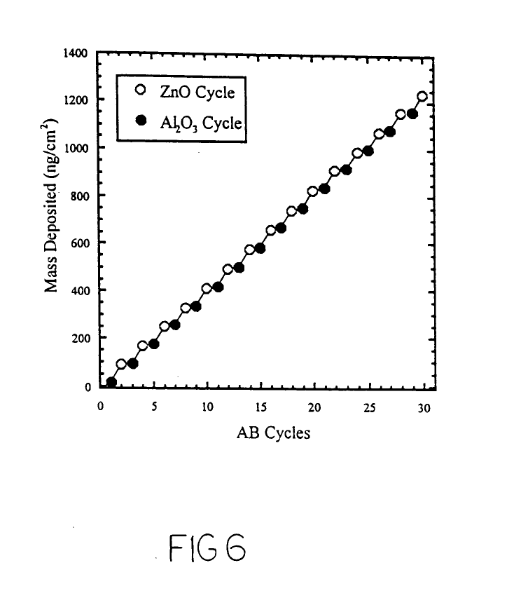

As mentioned supra, additional reactant channels can allow for the deposition of complex oxide materials. FIG. 6 depicts in situ QCM measurements recorded during the ALD pulse sequence: Al₂O₃/H₂O/DEZ/H₂O . . . As before, TMA is used to produce the alumina, and DEZ to produce the zinc oxide. The black circles in FIG. 6 represent zinc oxide ALD cycles while the open circles depict alumina ALD cycles. The larger mass increments during the zinc oxide ALD cycles are a consequence of the higher growth rate and greater density for zinc oxide compared to alumina. The stoichiometry of the ALD ZnₓAl_{Y}O films can be controlled by adjusting the relative number of DEZ and TMA pulses.

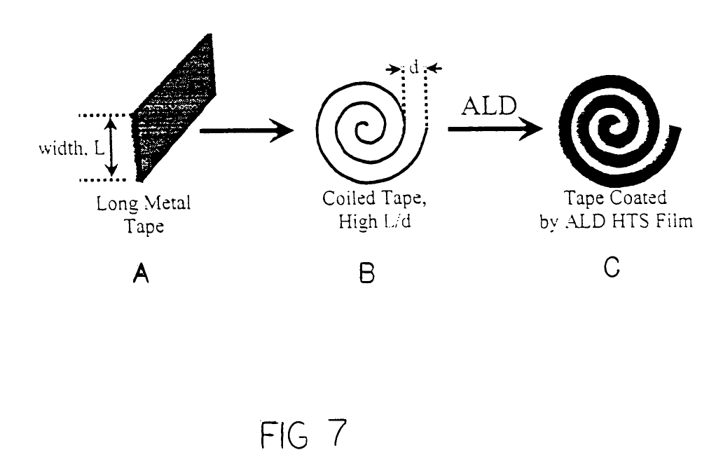

The reactor can achieve film growth rates on the order of a micron per hour while maintaining thickness uniformity and control on the atomic layer level. This rate is a normal and preferred rate of deposition for the instant invention, and is high relative to other methods. This rate is attainable with the instant invention regardless of the size of the substrate or size and nature of the reaction zone (flow tube). Accordingly, wires as long as 10 kilometers, even in coiled form as depicted in FIGS. 7A-C, can be coated on all sides, and all at once.

FIG. 7A depicts metal tape of width, L. The tape is coiled in FIG. 7B to give a high width (L) to loop separation distance (d) ratio as high as 10,000, which with other coating and deposition methods could restrict the coating of the tape surface. FIG. 7C shows the likely outcome with the instant invention, thorough and uniform coating of the tape with a consistent coating thickness along both surfaces of the tape.

The reactor can be utilized to grow a variety of high quality metal oxide films, such as manganites, high temperature superconducting cuprates, and ferroelectric perovskites.

The computerized gas pulse switching method for introducing the reactant moieties allows a plurality of materials to be grown on substrate surfaces, including oxide superlaftices, compound oxides, metals, and metal nitrides.

There are no physical limitations on the types of substrates that can be coated with an ALD-deposited film. Any size or shape of substrate can be coated with the instant invention. Two or more substrates can be coated at the same time.

The instant invention can be used to overcome the “weak-link” problem, i. e., intermittent breaks in conductivity, described supra. Controlled deposition of alternating atomic layers of different materials can facilitate the growth of multilayer YBCO/Ca-doped YBCO films. The completed deposition can be followed by annealing of the heterostructure to promote Ca diffusion. This effects the selective doping of the YBCO grain boundaries with Ca.

A combination of process variables must be carefully controlled to obtain optimized conditions. Key process variables include the deposition temperature, reactant dose, and length of precursor and purge pulses.

While the invention has been described with reference to details of the illustrated embodiments, these details are not intended to limit the scope of the invention as defined in the appended claims.

The embodiment of the invention in which an exclusive property or privilege is claimed is defined as follows:

1. A process for using a reaction sequence to deposit layers on a substrate, the process comprising:
a) placing the substrate in a chamber;
b) heating the chamber;
c) forming a first layer of a first gaseous precursor moiety molecules upon the substrate;
d) exposing the substrate and first layer to gaseous molecules of a second moiety at a concentration and for a time sufficient for the molecules of the second moiety to be absorbed to the first layer; and
e) allowing the first moiety to react with the second moiety so as to form a monolayer of product moiety molecules.

2. The process as recited in claim 1 wherein the process occurs at temperatures ranging from about 200° C. to 400° C.

3. The process as recited in claim 1 wherein the steps c through e are repeated.

4. The process as recited in claim 1 wherein steps c, d, and e are self-limiting.

5. The process as recited in claim 1 wherein the process is continuous.

6. The process as recited in claim 1 wherein more than three precursor moieties can be applied to the substrate's surface.

7. The process as recited in claim 1 wherein the carrier gas is selected from the group consisting of nitrogen, argon, and helium.

8. The process as recited in claim 1 wherein layers of product moiety are deposited as a film.

9. The process as recited in claim 8 wherein the film growth rate is up to about one micron (μ) per hour.

10. The process as recited in claim 1 wherein layers required for HTS superconductor materials can be deposited without removing the substrate from the process chamber.

11. The process as recited in claim 1 wherein inert carrier gas facilitates transport of the gaseous moieties into and out of the chamber.

12. The process as recited in claim 10 wherein layers of mixed yttrium oxides, barium oxides, copper oxides and calcium oxides are deposited onto the substrate to fabricate HTS superconductors.

13. The process as recited in claim 1 wherein each of the moieties are supplied to the chamber as a pulse of pure gas.

14. The process as recited in claim 13 wherein the pulse has a duration of between one tenth of a second and one second.

15. The process as recited in claim 13 wherein a pulse of inert gas is provided between each pulse of pure gas.

16. A device to facilitate conformal deposition of atomic layers upon substrates, the device comprising:
a) a reaction chamber;
b). a means for injecting fluid into the reaction chamber at pulsed intervals;
c) a means for removing the pulsed fluid from the reaction chamber; and
d) a means for regulating the atmosphere and temperature of the chamber.

17. The device as recited in claim 13 wherein the injecting means comprise valves for regulating the release of different precursor reactant moieties and inert carrier gas.

18. The device as recited in claim 13 wherein the atmosphere regulating means comprise vacuums to create negative pressure and effect gas flow through the device.

19. The device as recited in claim 13 wherein the atmosphere regulating means is capable of maintaining precursor reactant moieties in the vapor state.

20. The device as recited in claim 13 wherein the computerized gas pulse switch comprises a programmed computer and a pneumatic valve.
